(19) United States
(12) Patent Application Publication
(10) Pub. No.: US 2026/0313920 A1
(43) Pub. Date: Oct. 8, 2026

(54) METHOD OF MANUFACTURING CAPACITOR AND METHOD OF MANUFACTURING MEMORY DEVICE

(71) Applicant: EGTM Co., Ltd., Suwon-si (KR)

(72) Inventors: Kyu Ho CHO, Suwon-si, Gyeonggi-do (KR); Ju Hwan JEONG, Suwon-si, Gyeonggi-do (KR); Hyeon Sik CHO, Suwon-si, Gyeonggi-do (KR); Ha Na KIM, Suwon-si, Gyeonggi-do (KR); Jae Min KIM, Suwon-si, Gyeonggi-do (KR); Duck Hyeon SEO, Suwon-si, Gyeonggi-do (KR); Woong Jin CHOI, Suwon-si, Gyeonggi-do (KR)

(73) Assignee: EGTM Co., Ltd., Suwon-si (KR)

(21) Appl. No.: 19/642,122

(22) Filed: Apr. 8, 2026

(30) Foreign Application Priority Data
Apr. 8, 2025 (KR) 10-2025-0045785

(51) Int. Cl. H10D 1/00; H10P 50/26

(52) U.S. Cl. CPC H10D 1/043; H10P 50/266

(57) ABSTRACT

A method of manufacturing a capacitor comprises: forming a plurality of lower electrodes and a supporter layer supporting the lower electrodes on a substrate; etching the lower electrodes to expand a top critical dimension (TCD) of the lower electrodes; forming a dielectric layer on the lower electrodes and the supporter layers; and forming an upper electrode on the dielectric layer.

### CROSS-REFERENCE TO RELATED APPLICATIONS

This application claims priority to and the benefit of Korean Patent Application No. 10-2025-0045785, filed on 8 Apr. 2026, the disclosure of which is incorporated herein by reference in its entirety.

### BACKGROUND

### 1. Technical Field

The present invention relates to a method of manufacturing a capacitor and a method of manufacturing a memory device, and more particularly, to a method of manufacturing a capacitor having improved profile verticality and a method of manufacturing a memory device.

### 2. Related Art

As the integration density of semiconductor devices continues to increase, the precision of capacitor design including a metal-insulator-metal (MIM) structure for ensuring device performance and reliability has become increasingly important.

In particular, as the area that a capacitor can occupy continues to decrease due to the increasing integration density, the lower electrode must inevitably be formed in a structure having a high aspect ratio to secure sufficient capacitance. In order to secure high capacitance within a limited area, the height of the lower electrode must be further increased, and accordingly, securing an etching technique capable of ensuring the etch depth while maintaining the profile verticality has emerged as a key challenge.

However, as the aspect ratio increases, the difficulty of the etching process also increases. Generally, a space (opening) for forming the lower electrode is formed by etching a mold stack composed of mold layers and supporter layers, and ideally, a cylindrical structure having a vertical profile is desirable. However, the number of ions and radicals reaching the bottom decreases with the etch depth, and as a result, a reverse tapered structure in which the upper portion is wide and the lower portion is narrow may be formed. In addition, when a bowing phenomenon due to over-etching of the sidewall occurs, the verticality of the structure is further degraded.

Such non-ideal etch profiles cause the top critical dimension (TCD) between lower electrodes to become excessively narrow, which may lead to various problems such as a decrease in dielectric constant, local variations in film thickness, cell-to-cell interference, and localized leakage current during subsequent dielectric film deposition. Therefore, in order to secure profile verticality in the etching process, a process for sufficiently securing the top critical dimension between lower electrodes is necessary.

In addition, since high aspect ratio structures carry a risk of collapse or loss during subsequent processes, a supporter structure must be formed together to stably support the lower electrodes. However, in plasma-based etching methods, problems such as degradation of etch selectivity, increase in surface roughness, and structural damage frequently occur, and there are limitations in precise structural control. To overcome this, ALE (Atomic Layer Etching) technology has recently attracted attention. Since each cycle of ALE proceeds in a self-limiting manner, only the target layer can be precisely removed without excessive etching, and in particular, when applied to structures sensitive to damage such as lower electrodes composed of metallic materials, surface damage and increase in roughness can be minimized.

Therefore, there is a demand for a high-precision selective etching process, particularly an ALE-based process, that secures profile verticality and expands the top critical dimension while not causing damage to the supporter.

### PATENT DOCUMENTS

(Patent Document 1) Korean Patent Publication No. 2001-0049504 (published Jun. 15, 2001)

### SUMMARY

An object of the present invention is to provide a method of manufacturing a capacitor and a method of manufacturing a memory device capable of effectively expanding the top critical dimension (TCD) of a lower electrode in a high aspect ratio structure to improve profile verticality.

Another object of the present invention is to provide a method of manufacturing a capacitor and a method of manufacturing a memory device capable of selectively etching only the lower electrode without causing damage to the supporter layer.

Still another object of the present invention is to provide a method of manufacturing a capacitor and a method of manufacturing a memory device capable of improving the surface roughness of the lower electrode to enhance the uniformity of subsequent dielectric film deposition and dielectric constant characteristics.

Yet another object of the present invention is to provide a method of manufacturing a capacitor and a method of manufacturing a memory device capable of improving reliability.

The objects of the present invention are not limited to those described above, and other objects not mentioned herein will be clearly understood by those having ordinary skill in the art to which the present invention belongs from the present specification and the accompanying drawings.

According to an embodiment of the present invention, a method of manufacturing a capacitor comprises: forming a plurality of lower electrodes and a supporter layer supporting the lower electrodes on a substrate; etching the lower electrodes to expand the top critical dimension (TCD) of the lower electrodes; forming a dielectric layer on the lower electrodes and the supporter layers; and forming an upper electrode on the dielectric layer, wherein, in the step of expanding the top critical dimension of the lower electrodes, an etching amount at an upper region of the lower electrode is greater than an etching amount at a lower region of the lower electrode.

According to an embodiment of the present invention, the step of etching the lower electrode is an ALE process and may comprise supplying a reactant into a chamber in which the substrate is placed; purging an interior of the chamber; supplying an etchant into the interior of the chamber; and purging the interior of the chamber.

According to an embodiment of the present invention, the reactant and the etchant may be adsorbed relatively more at an upper region of the lower electrode and adsorbed relatively less toward a lower region as a concentration thereof decreases.

According to an embodiment of the present invention, the reactant may be provided as any one of O2, O3, H2O, and H2O2 alone, or in a mixture of at least two of O2, O3, H2O, and H2O2.

According to an embodiment of the present invention, the etchant may be at least one of dimethylformamide-dimethylacetal and 1-chloromethyl ethyl ether.

According to an embodiment of the present invention, in the step of etching the lower electrode, the supporter layer may have an etch selectivity with respect to the lower electrode.

According to an embodiment of the present invention, the step of etching the lower electrode may increase an aspect ratio of the lower electrode.

According to an embodiment of the present invention, the method may further comprise, between the step of expanding the top critical dimension of the lower electrodes and the step of forming the dielectric layer: forming an insulating layer on the lower electrodes and the supporter layers; and etching the insulating layer from a surface of the supporter layer.

According to an embodiment of the present invention, in the step of etching the insulating layer, the insulating layer may be selectively removed from the surface of the supporter layer.

According to an embodiment of the present invention, the lower electrode may have a high aspect ratio of 1:10 or greater.

According to an embodiment of the present invention, the lower electrode may comprise a metal, a metal nitride, a metal silicon nitride, a conductive metal oxide, a metal silicide, a noble metal, or a combination thereof.

According to an embodiment of the present invention, the supporter layer may comprise silicon nitride (Si3N4), silicon carbon nitride (SiCN), silicon boron nitride, or a combination thereof.

According to an embodiment of the present invention, the dielectric layer may comprise hafnium oxide (HfO2), zirconium oxide (ZrO2), aluminum oxide (Al2O3), titanium oxide (TiO2), tantalum oxide (Ta2O5), niobium oxide (Nb2O5), strontium titanium oxide (SrTiO3), or a combination or a stacked structure thereof.

According to an embodiment of the present invention, the insulating layer may comprise niobium oxide, niobium nitride, niobium oxynitride, tantalum oxide, yttrium oxide, lanthanum oxide, or a combination thereof.

According to an embodiment of the present invention, after the step of expanding the top critical dimension of the lower electrodes, the lower electrode may have a tapered shape in which a top critical dimension (TCD) of the lower electrode is greater than a bottom critical dimension (BCD) of the lower electrode.

According to an embodiment of the present invention, a method of manufacturing a memory device may comprise the above-described method of manufacturing a capacitor.

### BRIEF DESCRIPTION OF THE DRAWINGS

FIGS. 1A to 1F are views schematically showing a method of manufacturing a conventional capacitor.

FIGS. 2A to 2C are views schematically showing a method of manufacturing a capacitor according to an embodiment of the present invention.

FIG. 3 is a graph schematically showing a supply cycle according to an embodiment of the present invention.

FIGS. 4A and 4B show TEM analysis results of a titanium nitride film (TiN) before and after an ALE process according to an embodiment of the present invention.

FIGS. 5A and 5B show TEM analysis results of a silicon carbon nitride film (SiCN) before and after an ALE process according to an embodiment of the present invention.

FIGS. 6A to 6C are views comparing various types of lower electrodes.

FIGS. 7A to 7D show TEM analysis results of a titanium nitride film (TiN) before and after an ALE process according to an experimental example of the present invention.

FIGS. 8A to 8D show TEM analysis results of a titanium nitride film (TiN) before and after an ALE process according to an experimental example of the present invention.

FIGS. 9A to 9D show TEM analysis results of a titanium nitride film (TiN) before and after an ALE process according to an experimental example of the present invention.

FIGS. 10A to 10C are views schematically showing a method of manufacturing a capacitor according to another embodiment of the present invention.

FIGS. 11A to 11C are views schematically showing a method of manufacturing a capacitor according to still another embodiment of the present invention.

### DESCRIPTION OF EXAMPLE EMBODIMENTS

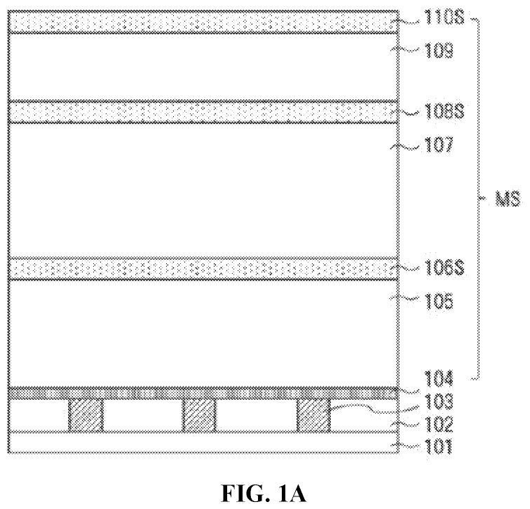

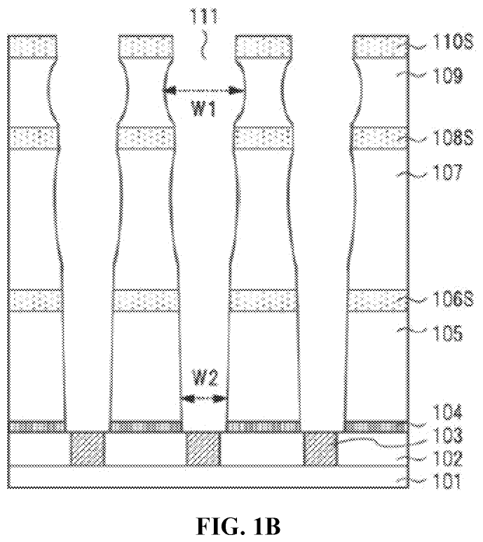

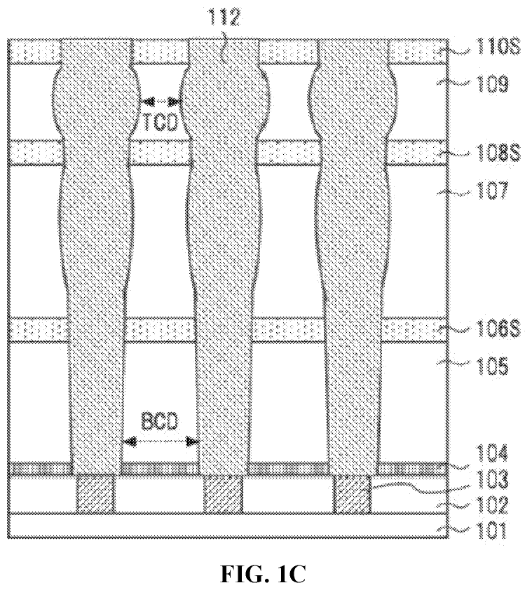

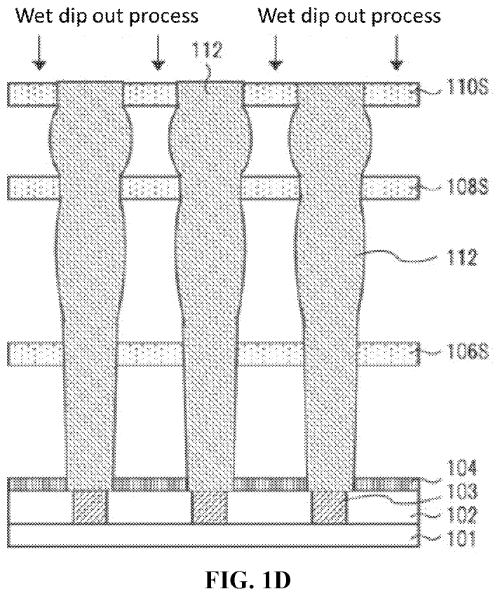

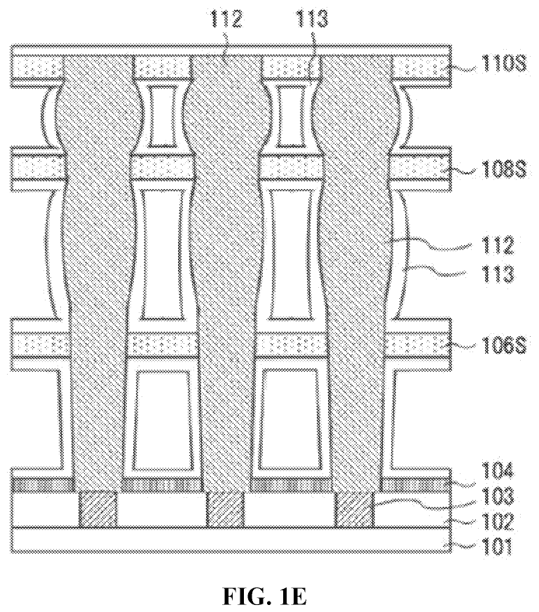

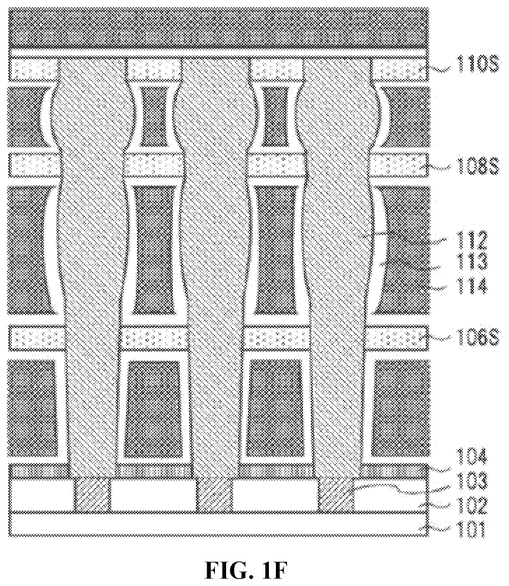

Hereinafter, preferred embodiments of the present invention will be described in more detail with reference to the accompanying FIGS. 1A to 11C. The embodiments of the present invention may be modified in various forms, and the scope of the present invention should not be construed as being limited to the embodiments described below. The embodiments are provided to explain the present invention in more detail to those having ordinary knowledge in the technical field to which the present invention belongs. Therefore, the shape of each element shown in the drawings may be exaggerated to emphasize a clearer explanation.

FIGS. 1A to 1F are views schematically showing a method of manufacturing a conventional capacitor. As shown in FIG. 1A, the capacitor may include a lower structure. The lower structure may be a stack structure including a substrate 101 and an interlayer insulating layer 102 on the substrate 101.

The substrate 101 may include a material suitable for semiconductor processing. For example, the substrate 101 may include a semiconductor substrate, and the semiconductor substrate may be made of a silicon-containing material. The semiconductor substrate may include silicon (Si), single crystal silicon, polysilicon, amorphous silicon, silicon-germanium (Si-Ge), single crystal silicon germanium, polycrystalline silicon germanium, carbon-doped silicon, a combination thereof, or a multilayer thereof. The semiconductor substrate may include other semiconductor materials such as germanium (Ge). The semiconductor substrate may include a III/V group semiconductor substrate, for example, a compound semiconductor substrate such as GaAs. The semiconductor substrate may include a silicon on insulator (SOI) substrate.

The interlayer insulating layer 102 may include BSG (Borosilicate Glass), PSG (PhosphoSilicate Glass), BPSG (BoroPhosphoSilicate Glass), TEOS (Tetra Ethyl Ortho Silicate), USG (Undoped Silicate Glass), or SOG (Spin On Glass).

The lower structure may include a plurality of contact plugs 103, and the contact plug 103 may be referred to as a storage node contact plug. The contact plug 103 is formed in the interlayer insulating layer 102 and may be connected to the substrate 101 through the interlayer insulating layer 102. The contact plug 103 may include polysilicon, a metal, a metal nitride, a metal silicide, or a combination or a stacked structure thereof. For example, the contact plugs 103 may include polysilicon, tungsten, tungsten nitride, titanium nitride, titanium silicon nitride, titanium silicide, cobalt silicide, or a combination thereof. In another embodiment, the contact plugs 103 may be stacked in the order of a semiconductor material, a metal silicide, a metal nitride, and a metal.

Although not shown, a plurality of word lines and bit lines may be formed on and/or in the substrate 101. The interlayer insulating layer 102 may be formed to cover the word lines and the bit lines. Impurity regions (not shown) may be formed in the substrate 101 on both sides of each of the word lines, and each of the contact plugs 103 may be connected to one of the impurity regions.

A mold stack layer MS may be formed on the lower structure, and the mold stack layer MS includes an etch stop layer 104, mold layers 105, 107, 109, and supporter layers 106S, 108S, 110S. For example, the mold stack layer MS may be stacked in the order of a lower mold layer 105, a lower supporter layer 106S, a middle mold layer 107, a middle supporter layer 108S, an upper mold layer 109, and an upper supporter layer 110S on the etch stop layer 104. The etch stop layer 104 may be formed on the interlayer insulating layer 102 and the contact plugs 103, and the etch stop layer 104 may include silicon nitride.

The mold layers 105, 107, 109 may be formed by chemical vapor deposition (CVD), atomic layer deposition (ALD), or physical vapor deposition (PVD). The mold layers 105, 107, 109 may include phosphorus-doped silicon oxide or boron-doped silicon oxide, and the mold layers may include USG, PSG, BSG, BPSG, FSG, or a combination thereof. The lower mold layer 105, the middle mold layer 107, and the upper mold layer 109 may each be different to have different etch rates in subsequent processes.

The supporter layers 106S, 108S, 110S may be formed by chemical vapor deposition (CVD), atomic layer deposition (ALD), or physical vapor deposition (PVD). The supporter layers 106S, 108S, 110S may include a material having etch selectivity with respect to the mold layers 105, 107, 109. Specifically, the supporter layers 106S, 108S, 110S may include silicon nitride (Si3N4), silicon carbon nitride (SiCN), silicon boron nitride, or a combination thereof, and the thicknesses of the lower supporter layer 106S, the middle supporter layer 108S, and the upper supporter layer 110S may each be different.

As shown in FIG. 1B, a plurality of openings 111 may be formed in the mold stack layer MS. The openings 111 may be formed by etching the mold stack layer MS using a mask layer (not shown). To form the openings 111, the upper supporter layer 110S, the upper mold layer 109, the middle supporter layer 108S, the middle mold layer 107, the lower supporter layer 106S, and the lower mold layer 105 may be sequentially etched using the mask layer as an etch barrier. The etching process for forming the openings 111 may stop at the etch stop layer 104.

To form the openings 111, dry etching, wet etching, or a combination thereof may be used. In addition, as the etching gas for forming the openings, a mixed gas plasma in which two or more of fluorocarbon gas, fluoromethane gas, argon gas, hydrogen gas (H2), and carbon dioxide (CO2) are mixed may be used.

The openings 111 may be referred to as holes in which the lower electrodes (or storage nodes) are to be formed. The opening 111 may have a high aspect ratio and may have an aspect ratio of at least 1:1 or greater. For example, the opening 111 may have a high aspect ratio of 1:10 or greater. The aspect ratio may refer to a ratio of a width to a height. Subsequently, the etch stop layer 104 may be etched to expose an upper surface of each of the contact plugs 103 below the openings 111.

Meanwhile, as shown in FIG. 1B, a problem occurs in which a lower portion W2 of the opening 111 is smaller than an upper portion W1 thereof (W1>W2). This is because dry etching is typically used in the etching process for forming the opening 111, and the etching efficiency decreases as the etching progresses toward the lower portion of the opening 111 due to the etching characteristics of the dry etching method.

As shown in FIG. 1C, a lower electrode 112 may be formed in each of the openings 111, and the lower electrode 112 may have a pillar shape. The lower electrodes 112 may fill the interiors of the openings 111 and may be electrically connected to the substrate 101 through the contact plugs 103.

The lower electrode 112 may be formed by chemical vapor deposition (CVD), atomic layer deposition (ALD), or physical vapor deposition (PVD). The lower electrode 112 may include a metal, a metal nitride, a metal silicon nitride, a conductive metal oxide, a metal silicide, a noble metal, or a combination thereof. The lower electrode 112 may include at least one of titanium (Ti), titanium nitride (TiN), titanium silicon nitride (TiSiN), tantalum (Ta), tantalum nitride (TaN), titanium aluminum nitride (TiAlN), tungsten (W), tungsten nitride (WN), ruthenium (Ru), ruthenium oxide (RuO2), iridium (Ir), iridium oxide (IrO2), platinum (Pt), molybdenum (Mo), or a combination thereof.

As shown in FIG. 1C, the conventional lower electrode 112 has a very narrow top critical dimension (TCD) compared to the bottom critical dimension (BCD) following the shape of the opening 111.

As shown in FIG. 1D, the mold layers 105, 107, 109 may be removed by a wet dip out process, thereby exposing the surface of the etch stop layer 104. The wet dip out process for removing the mold layers 105, 107, 109 may be performed using a wet chemical capable of selectively removing the mold layers 105, 107, 109. The wet chemical may use one or more chemicals such as HF, NH4F/NH4OH, H2O2, HCl, HNO3, H2SO4, and BOE (Buffered Oxide Etchant) solution.

As the mold layers 105, 107, 109 are removed, the outer wall of the lower electrode 112 may be partially exposed. When removing the mold layers 105, 107, 109, the supporter layers 106S, 108S, 110S having etch selectivity with respect to the mold layers 105, 107, 109 may remain without being removed, and the outer walls of the lower electrodes 112 may be supported by the supporter layers 106S, 108S, 110S.

As shown in FIG. 1E, a dielectric layer 113 may be formed. The dielectric layer 113 may be formed on the lower electrodes 112 and the supporter layers 106S, 108S, 110S, and a portion of the dielectric layer 113 may cover the lower structure.

As shown in FIG. 1F, an upper electrode 114 may be formed on the dielectric layer 113. The upper electrode 114 may fill a space between neighboring lower electrodes 112. The upper electrode 114 may extend to cover the upper portions of the lower electrodes 112.

Meanwhile, in the conventional method of manufacturing a capacitor, the gap between the dielectric layers 113 becomes very narrow following the shape of the lower electrode 112, which reduces the actual area covered by the dielectric layer, leading to a loss in dielectric constant and an increase in cell-to-cell interference. In addition, there is a problem that leakage current increases due to the non-uniform thickness of the dielectric layer 113, resulting in degradation of cell reliability and yield.

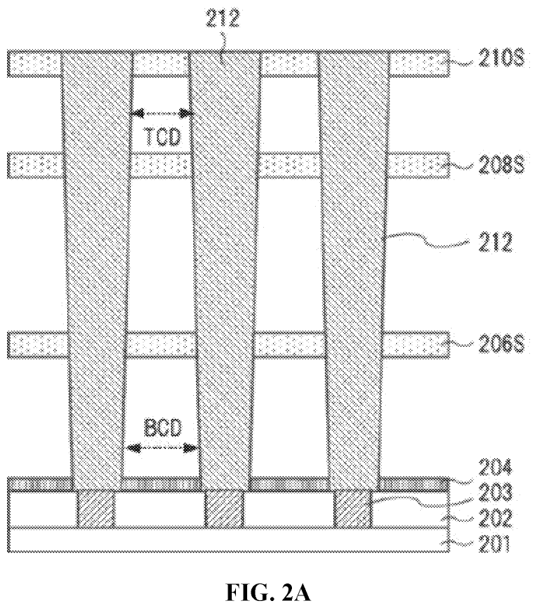

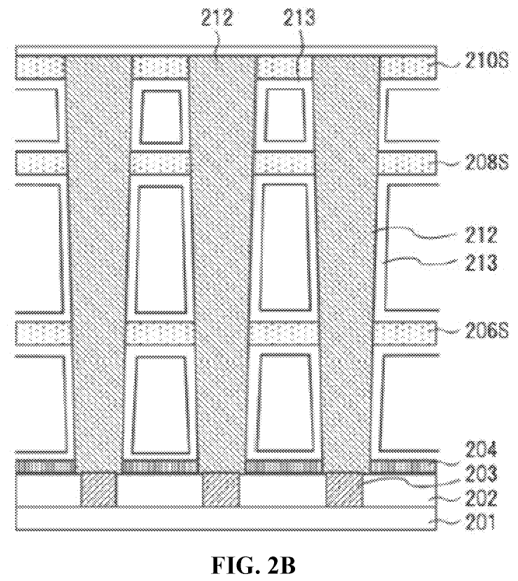

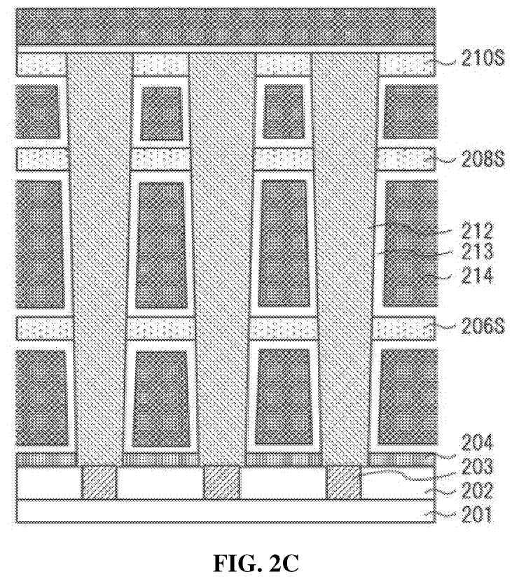

FIGS. 2A to 2C are views schematically showing a method of manufacturing a capacitor according to an embodiment of the present invention. Hereinafter, only portions different from the previously described content will be described, and descriptions omitted hereinafter may be replaced with the previously described content.

As shown in FIG. 2A, as the mold layers are removed, the outer wall of the lower electrode 212 may be partially exposed, and the supporter layers 206S, 208S, 210S having etch selectivity with respect to the mold layers may remain without being removed, and the outer walls of the lower electrodes 212 may be supported by the supporter layers 206S, 208S, 210S.

Thereafter, the lower electrode 212 may be etched to improve the profile, and the etching of the lower electrode 212 may be performed by ALE (Atomic Layer Etching). The aspect ratio of the lower electrode 212 may increase through the etching, and for example, the lower electrode 212 may have a high aspect ratio of 1:10 or greater.

Specifically, in one embodiment of the present application, the lower electrode 212 may be etched by an ALE process using one of O3, O2, H2O, or H2O2 as a reactant and any one of dimethylformamide-dimethylacetal and 1-chloromethyl ethyl ether as an etchant. The reactant and etchant used in the ALE process are over-adsorbed at the upper portion and the diffusion and concentration thereof decrease toward the lower portion, similar to the behavior of a precursor. Accordingly, the etching amount at the upper portion of the lower electrode 212 is greater than that at the lower portion, so that the reverse tapered structure or bowing phenomenon occurring in the conventional opening formation process can be effectively improved to secure profile verticality. In addition, since each cycle of the ALE process proceeds in a self-limiting manner, the lower electrode 212 can be selectively etched without damage to the supporter layers 206S, 208S, 210S, thereby improving the profile of the lower electrode 212 to form an opening 211 that is deeper and has a greater aspect ratio than the conventional process, and the uniformity of subsequent dielectric film deposition and dielectric constant characteristics described below can also be improved.

Thereafter, as shown in FIG. 2B, a dielectric layer 213 may be formed. The dielectric layer 213 may be formed on the lower electrodes 212 and the supporter layers 206S, 208S, 210S, and a portion of the dielectric layer 213 may cover the lower structure. The dielectric layer 213 may include a high-k material having a higher dielectric constant than silicon oxide. The high-k material may include hafnium oxide (HfO2), zirconium oxide (ZrO2), aluminum oxide (Al2O3), titanium oxide (TiO2), tantalum oxide (Ta2O5), niobium oxide (Nb2O5), or strontium titanium oxide (SrTiO3). The dielectric layer 213 may also include a combination or a stacked structure thereof. In addition, the dielectric layer 213 may include a ZAZ (ZrO2/Al2O3/ZrO2) stack, a ZAZA (ZrO2/Al2O3/ZrO2/Al2O3) stack, a ZAZAT (ZrO2/Al2O3/ZrO2/Al2O3/TiO2) stack, a HAH (HfO2/Al2O3/HfO2) stack, a TZAZ (TiO2/ZrO2/Al2O3/ZrO2) stack, a TiO2/HfO2/Al2O3/HfO2 stack, a Ta2O5/ZrO2/Al2O3/ZrO2 stack, or a Ta2O5/HfO2/Al2O3/HfO2 stack.

Thereafter, as shown in FIG. 2C, an upper electrode 214 may be formed on the dielectric layer 213. The upper electrode 214 may fill a space between neighboring lower electrodes 212. The upper electrode 214 may extend to cover the upper portions of the lower electrodes 212. The upper electrode 214 may include polysilicon, silicon germanium, a metal, a metal nitride, a metal silicon nitride, a conductive metal oxide, a metal silicide, a noble metal, or a combination thereof. The upper electrode 214 may include at least one of titanium (Ti), titanium nitride (TiN), titanium silicon nitride (TiSiN), tantalum (Ta), tantalum nitride (TaN), titanium aluminum nitride (TiAlN), tungsten (W), tungsten nitride (WN), ruthenium (Ru), ruthenium oxide (RuO2), iridium (Ir), iridium oxide (IrO2), platinum (Pt), molybdenum (Mo), or a combination thereof.

According to the above description, a conformal dielectric layer can be formed, and the effective area is increased, thereby improving the reliability of the capacitor through an increase in dielectric constant, a decrease in leakage current, and the like.

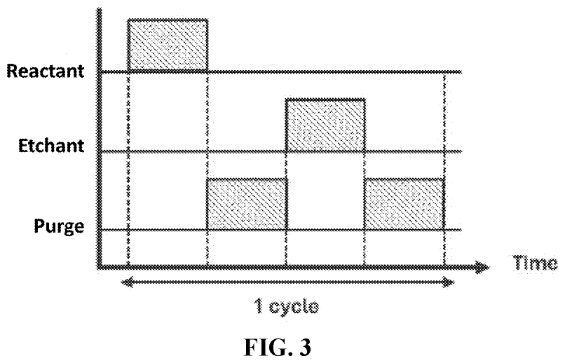

FIG. 3 is a graph schematically showing a supply cycle according to an embodiment of the present invention. First, a semiconductor device loaded inside a chamber has the mold layers removed through the preceding process, and the semiconductor device is exposed to a reactant supplied into the interior of the chamber.

The reactant may be provided as any one of O2, O3, H2O, and H2O2 alone, or in a mixture of at least two of O2, O3, H2O, and H2O2. Specifically, the reactant may include at least one selected from the group consisting of O2, O3, H2O, and H2O2, and if necessary, may be provided in a mixture of at least two of O2, O3, H2O, and H2O2.

Thereafter, a purge gas (for example, an inert gas such as Ar) is supplied into the interior of the chamber to remove or purify residual reactant or by-products.

Thereafter, the semiconductor device is exposed to an etchant (or reactive gas) supplied into the interior of the chamber, and the etching of the substrate is activated by the etchant.

As the etchant, any one of dimethylformamide-dimethylacetal and 1-chloromethyl ethyl ether may be used. However, this is merely an example and should not be construed in a limiting manner. As the etchant, any suitable material having a similar structure to or performing a similar function as dimethylformamide-dimethylacetal or 1-chloromethyl ethyl ether may be used. Specifically, bis(dimethylamino)methoxymethane, trimethyl orthoformate, trimethyl orthoacetate, and/or dichloromethyl methyl ether, which have a similar structure to or a similar function as dimethylformamide-dimethylacetal or 1-chloromethyl ethyl ether, are also applicable as etchants of the present invention. Thereafter, a purge gas (for example, an inert gas such as Ar) is supplied into the interior of the chamber to remove or purify residual etchant or by-products.

Meanwhile, the reactant and the etchant are over-adsorbed at the upper portion and the diffusion and concentration thereof decrease toward the lower portion, similar to the behavior of a precursor. Therefore, the top critical dimension (TCD) of the lower electrode 212 can be expanded compared to the conventional process. Specific details regarding before and after the ALE process and the effects thereof will be described later.

According to an embodiment of the present application, the reactant may include a reactive species activated in a plasma state. As an example, O2 plasma may be used as a reactant. The reactant in a plasma state may improve reactivity and enable the process even under low-temperature process conditions.

Specifically, O2 plasma may be generated by various plasma generation methods. For example, O2 plasma may be generated by applying a capacitively coupled plasma (CCP) method, an inductively coupled plasma (ICP) method, and/or other plasma generation methods.

In addition, the plasma may be provided in a remote plasma method or a direct plasma method.

By using a reactant in a plasma state, the present invention is applicable not only to an ALD process using a thermal reaction but also to a plasma-enhanced atomic layer deposition (PEALD) process and an atomic layer etching (ALE) process, and the type and supply method of the reactant may be selectively adjusted according to process conditions and required thin film characteristics.

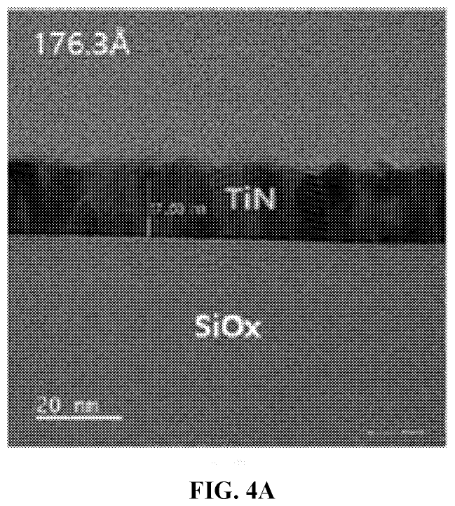

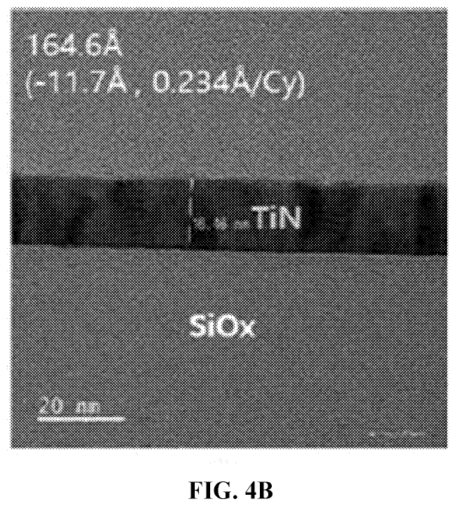

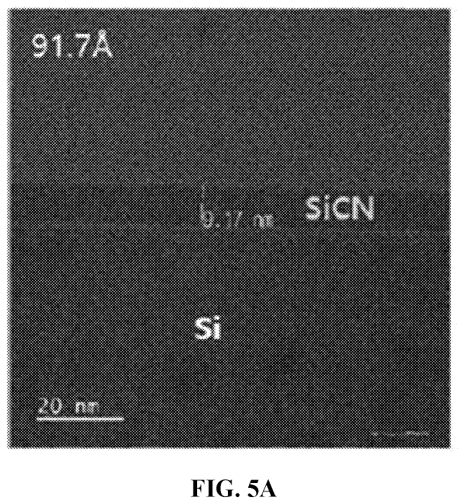

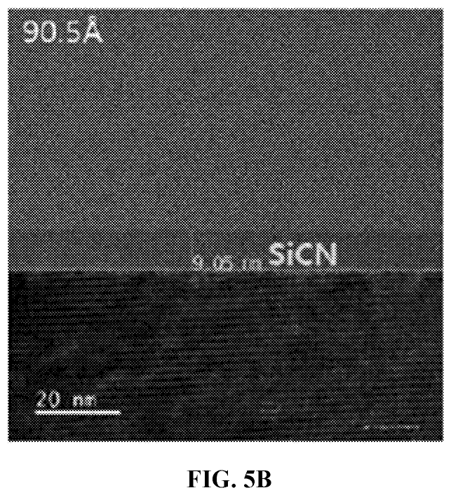

Hereinafter, the etch characteristics and selectivity of the ALE process for each material will be described with reference to FIGS. 4A, 4B, 5A, and 5B.

FIGS. 4A and 4B show TEM analysis results of a titanium nitride film (TiN) before and after an ALE process according to an embodiment of the present invention, and FIGS. 5A and 5B show TEM analysis results of a silicon carbon nitride film (SiCN) before and after an ALE process according to an embodiment of the present invention.

A titanium nitride (TiN) thin film deposited on a silicon oxide substrate and a silicon carbon nitride (SiCN) thin film deposited on a Si substrate were simultaneously loaded into the chamber. The ALE process was performed using O3 as a reactant and dimethylformamide-dimethylacetal as an etchant according to the supply cycle of FIG. 3, and etching was performed by repeating 50 cycles at a process temperature of 340 degrees C.

As shown in FIGS. 4A and 4B, it was confirmed that the titanium nitride film (TiN) was etched by 11.7 angstroms through the ALE process, and since the EPC (etch per cycle) was approximately 0.23 angstroms/cycle and the thickness decreased linearly, it was confirmed that the thickness of the titanium nitride film (TiN) can be precisely controlled by adjusting the number of ALE process cycles. In addition, it was confirmed that the roughness (Rq) of the titanium nitride film (TiN) was improved from 0.8 nm to 0.6 nm through the ALE process.

As shown in FIGS. 5A and 5B, in the case of the silicon carbon nitride film (SiCN), the thickness change before and after the ALE process was observed to be at a level of 1.2 angstroms, and the change amount was insignificant. In addition, it was confirmed that the roughness (Rq) of the silicon carbon nitride film (SiCN) was 0.2 nm before and 0.21 nm after the ALE process, confirming that there was almost no surface damage or change.

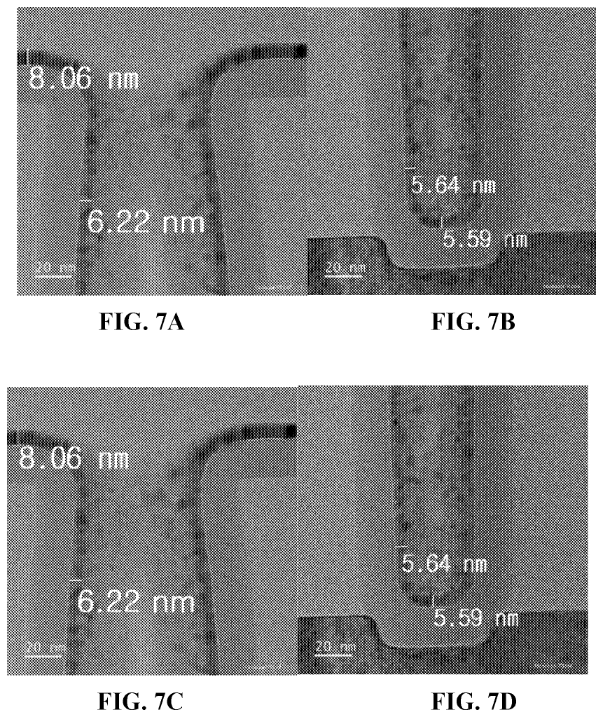

From the above results, it was confirmed that the ALE process can precisely control the thickness of the titanium nitride film (TiN) with a constant etch per cycle (EPC) per cycle, while exhibiting high etch selectivity in which etching hardly proceeds for the silicon carbon nitride film (SiCN). This is attributable to the self-limiting characteristic of the ALE process, in which each reaction cycle is limited to surface reactions only, thereby suppressing excessive etching. Therefore, when the ALE process is applied to an actual high aspect ratio structure, it can be seen that this serves as a basis for selectively etching only the lower electrode 212 without damage to the supporter layers 206S, 208S, 210S. Based on this difference in etch selectivity, the titanium nitride film (TiN) may be used as a lower electrode 212 that is selectively etched by the ALE process, and the silicon carbon nitride film (SiCN) may be used as supporter layers 206S, 208S, 210S that stably support the structure without being etched in the ALE process. Furthermore, as shown in FIGS. 7A to 9D described later, the effects of top critical dimension (TCD) expansion and step coverage improvement of the lower electrode were experimentally confirmed even when the ALE process was applied to an actual high aspect ratio hole pattern wafer.

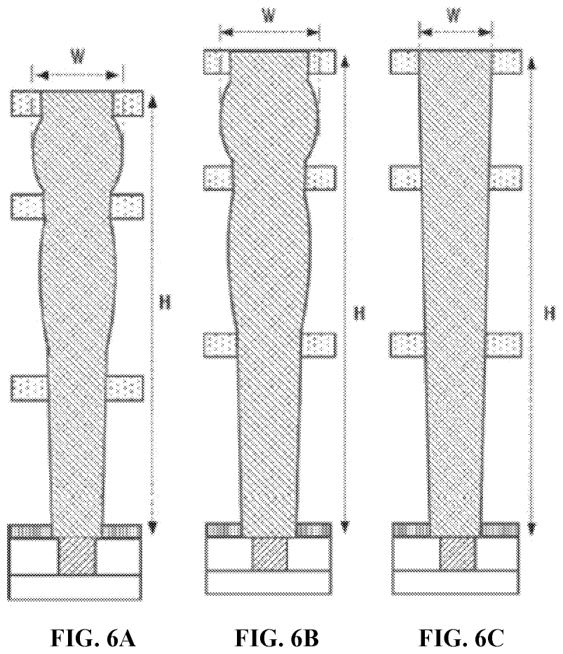

FIGS. 6A to 6C are views comparing various types of lower electrodes. FIG. 6A shows a lower electrode (aspect ratio of 1:10) resulting from the limitations of the conventional opening etching process (W=15 nm, H=150 nm). FIG. 6B shows a lower electrode (aspect ratio of 1:10) in which neither the height (H) nor the width (W) can be selectively increased due to the limitations of the conventional opening etching process, and the aspect ratio is the same as FIG. 6A (W=16 nm, H=160 nm). FIG. 6C shows a lower electrode (aspect ratio of 1:10.7) having an improved aspect ratio by etching the lower electrode of FIG. 6B according to an embodiment of the present invention (W=15 nm, H=160 nm). Specifically, FIGS. 6A to 6C and Table 1 below are views schematically showing the effect of improving the aspect ratio of the lower electrode when the ALE process according to the present invention is applied. According to an embodiment of the present invention, the lower electrode of FIG. 6B is etched to improve the aspect ratio and profile verticality, thereby increasing the effective area and improving the dielectric film. Table 1 below shows the width/height and aspect ratio of the lower electrodes shown in FIGS. 6A to 6C.

| Aspect Ratio Example | FIG. 6A | FIG. 6B | FIG. 6C |
|---|---|---|---|
| W (nm) | 15 | 16 | 15 |
| H (nm) | 150 | 160 | 160 |
| Lower Electrode Aspect Ratio | 1:10 | 1:10 | 1:10.7 |

Meanwhile, in FIGS. 7A to 9D described later, it is intended to demonstrate that the effects of the present invention can be realized even under extreme high aspect ratio conditions ranging from an aspect ratio of 1:30 to 1:50 through experiments using actual hole pattern wafers.

Hereinafter, the effects of the ALE process according to various combinations of reactants and etchants under more extreme high aspect ratio conditions will be described with reference to FIGS. 7A to 9D. In each of FIGS. 7A to 9D, the A and B drawings show the top and bottom TEM images of the state before the ALE process (Reference), and the C and D drawings show the top and bottom TEM images of the state after the ALE process (Experimental Example). Specifically, the TEM data in FIGS. 7A to 9D are data interpreted based on the top side.

FIGS. 7A to 7D show TEM analysis results before and after the ALE process under a certain aspect ratio condition according to an experimental example (Experimental Example 1) of the present invention. In Experimental Example 1, the ALE process was performed using 1-chloromethyl ethyl ether as an etchant and an aqueous H2O2 solution as a reactant at a process temperature of 300 degrees C. The etchant was supplied into the chamber at 0.1 g/min through a LFM (Liquid Flow Meter) method. The reactant was supplied through a vapor method, and the temperature of the storage vessel was maintained at 40 degrees C.

The pattern wafer used had a top CD gap of approximately 52 nm and a hole structure with an aspect ratio of 1:30. Table 2 below shows the TEM analysis results before and after the ALE process according to FIGS. 7A to 7D.

| | Before ALE | After ALE |
|---|---|---|
| | Process | Process |
| Thin Film Upper Thickness (angstroms) | 62.2 | 48.8 |
| Step Coverage (%) | 90.7 | 100.2 |

As shown in Table 2, the upper TiN thin film thickness of the lower electrode before the ALE process was reduced from 62.2 angstroms to 48.8 angstroms after the ALE process, confirming that the opening was expanded by approximately 26 angstroms (approximately twice the thickness change amount (13.4 angstroms) of the upper TiN thin film). The step coverage of the pattern before the ALE process was 90.7%, but increased to 100.2% after the ALE process, indicating that the step coverage was improved. In addition, based on the thickness reduced by the ALE process, the etching ratio of the upper portion relative to the lower portion was approximately 56%, confirming that etching proceeded predominantly in the upper region. Therefore, it was confirmed that by applying the atomic layer etching process proposed in the present invention, the top critical dimension can be expanded in the lower electrode structure and the profile verticality of the pattern can be improved.

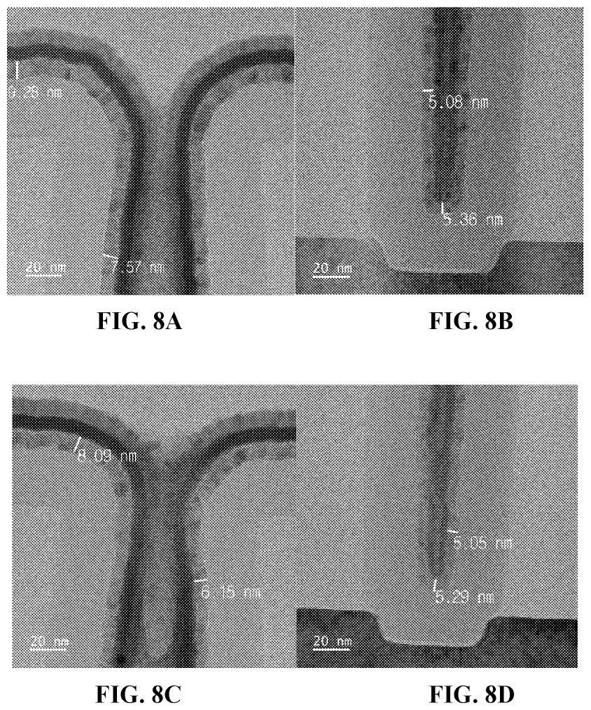

FIGS. 8A to 8D show TEM analysis results before and after the ALE process according to an experimental example (Experimental Example 2) of the present invention. In Experimental Example 2, the ALE process was performed using 1-chloromethyl ethyl ether as an etchant and O3 at 140 g/m3 as a reactant at a process temperature of 300 degrees C. The etchant was supplied into the chamber at 0.1 g/min through a LFM method. The pattern wafer used had a top CD gap of approximately 30 nm and a hole structure with an aspect ratio of 1:50. Table 3 below shows the TEM analysis results before and after the ALE process according to FIGS. 8A to 8D.

| | Before ALE | After ALE |
|---|---|---|
| | Process | Process |
| Thin Film Upper Thickness | 75.7 | 61.5 |
| (angstroms) | | |
| Step Coverage (%) | 67.1 | 82.1 |

As shown in FIGS. 8A to 8D, the upper TiN thin film thickness before the ALE process was reduced from 75.7 angstroms to 61.5 angstroms, confirming that the opening was expanded by approximately 28 angstroms (approximately twice the thickness change amount (14.2 angstroms) of the upper TiN thin film). The step coverage of the pattern before the ALE process was 67.1%, but increased to 82.1% after the ALE process, indicating that the step coverage was improved. In addition, based on the thickness reduced by the ALE process, the etching ratio of the upper portion relative to the lower portion was approximately 2%, confirming that etching proceeded very predominantly in the upper region. Therefore, it was confirmed that by applying the atomic layer etching process proposed in the present invention, the top critical dimension can be expanded in the lower electrode structure and the profile verticality of the pattern can be improved.

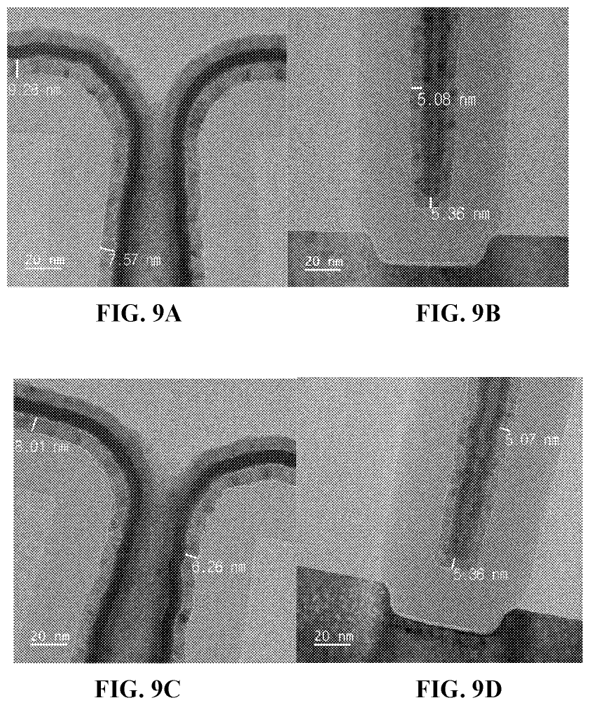

FIGS. 9A to 9D show TEM analysis results before and after the ALE process according to an experimental example (Experimental Example 3) of the present invention. In Experimental Example 3, the ALE process was performed using dimethylformamide-dimethylacetal as an etchant and O3 at 120 g/m3 as a reactant at a process temperature of 320 degrees C. The etchant was supplied into the chamber at 0.1 g/min through a LFM method. The pattern wafer used had a top CD gap of approximately 30 nm and a hole structure with an aspect ratio of 1:50. The Reference [FIGS. 9A and 9B] of Experimental Example 3 used the same pattern wafer as Experimental Example 2. Table 4 below shows the TEM analysis results before and after the ALE process according to FIGS. 9A to 9D.

| | Before ALE | After ALE |
|---|---|---|
| | Process | Process |
| Thin Film Upper Thickness | 75.7 | 62.6 |
| (angstroms) | | |
| Step Coverage (%) | 67.1 | 81.0 |

As shown in FIGS. 9A to 9D, the upper TiN thin film thickness before the ALE process was reduced from 75.7 angstroms to 62.6 angstroms, confirming that the opening was expanded by approximately 26 angstroms (approximately twice the thickness change amount (13.1 angstroms) of the upper TiN thin film). The step coverage of the pattern before the ALE process was 67.1%, but increased to 81.0% after the ALE process, indicating that the step coverage was improved. In addition, based on the thickness reduced by the ALE process, the etching ratio of the upper portion relative to the lower portion was approximately 1%, confirming that etching proceeded very predominantly in the upper region. Therefore, it was confirmed that by applying the atomic layer etching process proposed in the present invention, the top critical dimension can be expanded in the lower electrode structure and the profile verticality of the pattern can be improved.

Table 5 below compares the ALE process conditions and TiN pattern wafer analysis results according to Experimental Examples 1 to 3.

| | | | | ALE Sequence | Hole PW: | Lower | Etch | TiN |
|---|---|---|---|---|---|---|---|---|
| | | | Temp. | (Reactant- | Upper Etch | Etch | Thickness | Thickness |
| | | React. | (degrees | Purge-Etchant- | Thickness | Thickness | Step | Step |
| Exp. | Source (Etchant) | (Reactant) | C.) | Purge) | (angstroms) | (angstroms) | Coverage | Coverage |
| 1 | 1-chloromethyl | H2O2 | 300 | 5 s-15 s- | 13.4 | 7.5 | 56% | 100.2% |
| | ethyl ether | aqueous | | 60 s-30 s | | | | |
| | | solution | | | | | | |
| 2 | 1-chloromethyl | O3 140 | 300 | 1 s-15 s- | 14.2 | 0.3 | 2% | 82.1% |
| | ethyl ether | g/m3 | | 70 s-30 s | | | | |
| 3 | Dimethylformamide- | O3 120 | 320 | 1 s-15 s- | 13.1 | 0.1 | 1% | 81.0% |
| | Dimethylacetal | g/m3 | | 60 s-30 s | | | | |

From the results of Experimental Examples 1 to 3, it was confirmed that regardless of the combination of the reactant (H2O2 or O3) and the etchant (1-chloromethyl ethyl ether or dimethylformamide-dimethylacetal), the top critical dimension (TCD) of the lower electrode was expanded and the step coverage was improved by the ALE process even under extreme high aspect ratio conditions of 1:30 to 1:50. In particular, in all three experimental examples, it was confirmed that the TiN thickness of the bottom TEM (FIGS. 7D, 8D, and 9D) was maintained at a similar level to the Reference while etching proceeded predominantly only at the top (FIGS. 7C, 8C, and 9C), which is attributable to the characteristic that the reactant and etchant in the ALE process are over-adsorbed at the upper portion and the concentration decreases toward the lower portion. In addition, Experimental Examples 2 and 3 using O3 as a reactant (etching ratios of 2% and 1%, respectively) exhibited higher upper selectivity compared to Experimental Example 1 using H2O2 (56%), suggesting that the type of reactant affects the upper selectivity of the ALE process.

Summarizing the results of FIGS. 7A to 9D, it was progressively demonstrated that the TiN/SiCN etch selectivity confirmed at the blanket thin film level can be effectively realized in actual high aspect ratio hole pattern structures by the ALE process.

FIGS. 7A to 9D extended this to extreme aspect ratio conditions of 1:30 (Experimental Example 1) and 1:50 (Experimental Examples 2 and 3) and verified by diversifying the etchant combinations to 1-chloromethyl ethyl ether (Experimental Examples 1 and 2) and dimethylformamide-dimethylacetal (Experimental Example 3). In all three experimental examples, the upper TiN thin film thickness decreased after the ALE process, the opening was expanded, and the step coverage was improved, and in particular, the lower TiN thickness was maintained at a similar level to the Reference, confirming that selective etching at the upper portion proceeded predominantly. This is attributable to the inherent behavior of the ALE process in which the reactant and etchant are over-adsorbed at the upper portion and the concentration decreases toward the lower portion, and it suggests that this concentration gradient effect becomes more pronounced as the aspect ratio increases.

From the above results, it was experimentally demonstrated that the ALE process proposed in the present invention can adjust the degree of upper selectivity according to the selection of the reactant and etchant combination, and can stably realize the effects of top critical dimension (TCD) expansion and step coverage improvement of the lower electrode even under extreme high aspect ratio conditions ranging from an aspect ratio of 1:30 to 1:50.

In the conventional plasma-based etching method, there was a problem that the top critical dimension (TCD) between lower electrodes became excessively narrow because ions and radicals could not uniformly reach the lower portion of the high aspect ratio structure, and there were technical difficulties in optimizing process conditions to overcome this. In particular, when the TCD between lower electrodes narrows, thickness variations occur during subsequent dielectric film deposition, the dielectric constant decreases, and cell-to-cell interference and leakage current increase, directly affecting the reliability of the capacitor.

In contrast, according to an embodiment of the present application, the reactant and etchant used in the ALE process exhibit characteristics in which they are over-adsorbed at the upper portion of the high aspect ratio structure and the diffusion and concentration thereof decrease toward the lower portion, similar to the behavior of a precursor. Accordingly, in the etching step of expanding the top critical dimension (TCD) of the lower electrodes, the etching amount at the upper region of the lower electrode is greater than the etching amount at the lower region. Specifically, as shown in FIGS. 7A to 9D, the etching ratios of the upper portion relative to the lower portion based on the thickness reduced by the ALE process in Experimental Examples 1 to 3 were approximately 56%, 2%, and 1%, respectively, experimentally confirming that etching in the upper region proceeded predominantly over the lower region regardless of the reactant and etchant combination. Due to this upper-predominant etching behavior, the top critical dimension (TCD) of the lower electrode is selectively expanded to improve profile verticality, and the effects of improving the uniformity of subsequent dielectric film deposition and dielectric constant characteristics can be provided even under extreme high aspect ratio conditions ranging from an aspect ratio of 1:30 to 1:50.

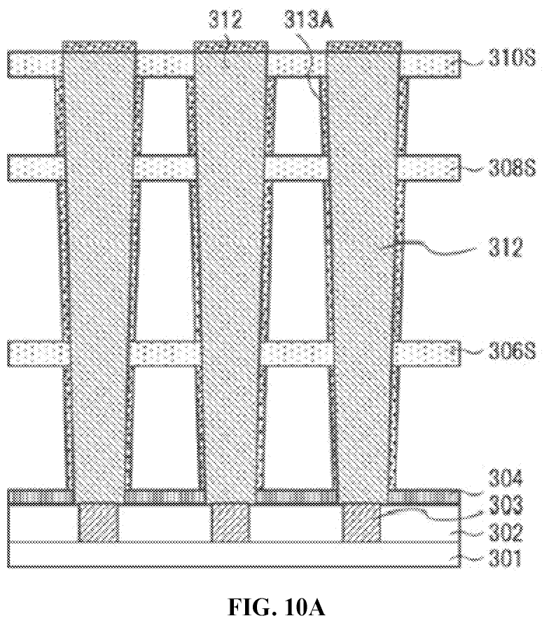

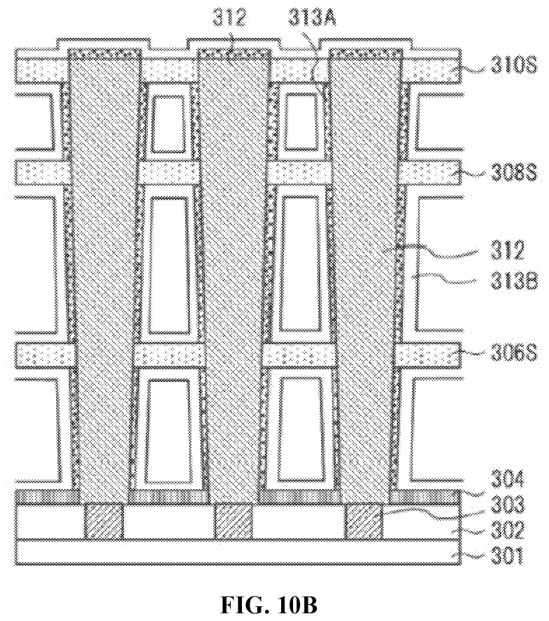

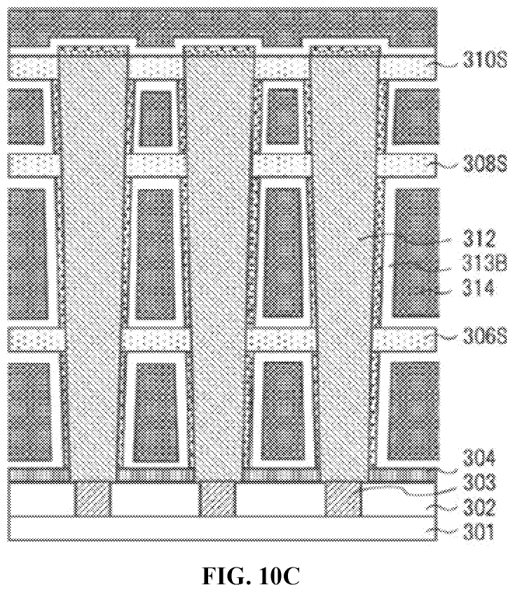

FIGS. 10A to 10C are views schematically showing a method of manufacturing a capacitor according to another embodiment of the present invention. Hereinafter, only portions different from the previously described content will be described, and descriptions omitted hereinafter may be replaced with the previously described content.

As described above, as the mold layers are removed, the outer wall of the lower electrode 312 may be partially exposed, and the supporter layers 306S, 308S, 310S having etch selectivity with respect to the mold layers may remain without being removed, and the outer walls of the lower electrodes 312 may be supported by the supporter layers 306S, 308S, 310S.

Thereafter, as shown in FIG. 10A, an insulating layer 313A for improving interfacial characteristics may be formed on the lower electrode 312. In general, the interfacial characteristics of the lower electrode surface may affect the uniformity of subsequent dielectric layer deposition and leakage current characteristics. Therefore, by selectively forming the insulating layer 313A on the surface of the lower electrode 312, the interfacial characteristics can be improved, and the reliability of the dielectric layer 313B deposition can be enhanced. The insulating layer 313A may include niobium oxide (Nb-oxide, NbOx), niobium nitride, niobium oxynitride, tantalum oxide (Ta-oxide, TaOx), yttrium oxide, or lanthanum oxide. At this time, the insulating layer 313A may be formed thinner on the surface of the supporter layers 306S, 308S, 310S than on the surface of the lower electrode 312, and may be formed by selective deposition.

For example, the selective deposition of the insulating layer 313A may use a surface passivation treatment material. Specifically, the selective deposition of the insulating layer 313A may include injection and purging of the surface passivation material, injection and purging of a precursor, and injection and purging of a reactive gas, and the injection and purging of the precursor and the injection and purging of the reactive gas may be repeated for 1 cycle to 100 cycles. The surface passivation material may include an organic compound containing hydrogen or hydrocarbon. The purge gas may include an inert gas such as argon, and the reactive gas may use any one of H2O, O3, H2O2, or O2.

Thereafter, an etchback process (for example, an ALE process) for etching the insulating layer 313A may be performed, and since the insulating layer 313A may be formed thinner on the surface of the supporter layers 306S, 308S, 310S than on the surface of the lower electrode 312, the insulating layer 313A may be removed from the surface of the supporter layers 306S, 308S, 310S.

Thereafter, as shown in FIG. 10B, a dielectric layer 313B may be formed. The dielectric layer 313B may be formed on the lower electrodes 312 and the supporter layers 306S, 308S, 310S, and a portion of the dielectric layer 313B may cover the lower structure. The dielectric layer 313B may include a high-k material having a higher dielectric constant than silicon oxide. The high-k material may include hafnium oxide (HfO2), zirconium oxide (ZrO2), aluminum oxide (Al2O3), titanium oxide (TiO2), tantalum oxide (Ta2O5), niobium oxide (Nb2O5), or strontium titanium oxide (SrTiO3). The dielectric layer 313B may also include a combination or a stacked structure thereof. In addition, the dielectric layer 313B may include a ZAZ (ZrO2/Al2O3/ZrO2) stack, a ZAZA (ZrO2/Al2O3/ZrO2/Al2O3) stack, a ZAZAT (ZrO2/Al2O3/ZrO2/Al2O3/TiO2) stack, a HAH (HfO2/Al2O3/HfO2) stack, a TZAZ (TiO2/ZrO2/Al2O3/ZrO2) stack, a TiO2/HfO2/Al2O3/HfO2 stack, a Ta2O5/ZrO2/Al2O3/ZrO2 stack, or a Ta2O5/HfO2/Al2O3/HfO2 stack.

Thereafter, as shown in FIG. 10C, an upper electrode 314 may be formed on the dielectric layer 313B. The upper electrode 314 may fill a space between neighboring lower electrodes 312. The upper electrode 314 may extend to cover the upper portions of the lower electrodes 312. The upper electrode 314 may include polysilicon, silicon germanium, a metal, a metal nitride, a metal silicon nitride, a conductive metal oxide, a metal silicide, a noble metal, or a combination thereof. The upper electrode 314 may include at least one of titanium (Ti), titanium nitride (TiN), titanium silicon nitride (TiSiN), tantalum (Ta), tantalum nitride (TaN), titanium aluminum nitride (TiAlN), tungsten (W), tungsten nitride (WN), ruthenium (Ru), ruthenium oxide (RuO2), iridium (Ir), iridium oxide (IrO2), platinum (Pt), molybdenum (Mo), or a combination thereof.

According to the above description, the insulating layer 313A uniformly modifies the chemical characteristics of the surface of the lower electrode 312, thereby stabilizing the nucleation behavior during subsequent dielectric layer 313B deposition, and through this, a conformal dielectric layer in which the dielectric layer 313B is formed to a uniform thickness over the entire surface of the lower electrode 312 can be realized. In addition, since the insulating layer 313A is removed from the surface of the supporter layers 306S, 308S, 310S by etchback, the dielectric layer 313B is directly deposited on both the supporter layer surface and the lower electrode surface, enabling conformal coverage over the entire structure. Accordingly, the effective area is increased, thereby improving the reliability of the capacitor through an increase in dielectric constant, a decrease in leakage current, and the like.

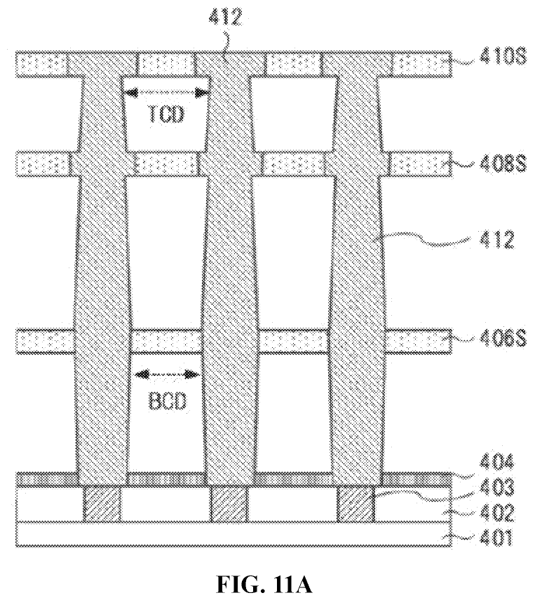

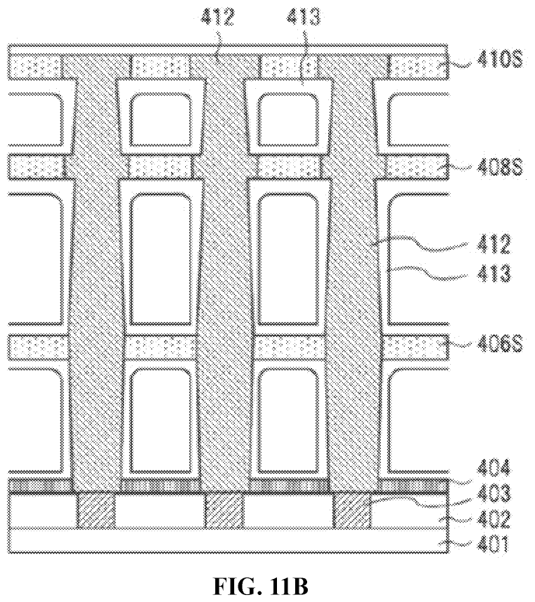

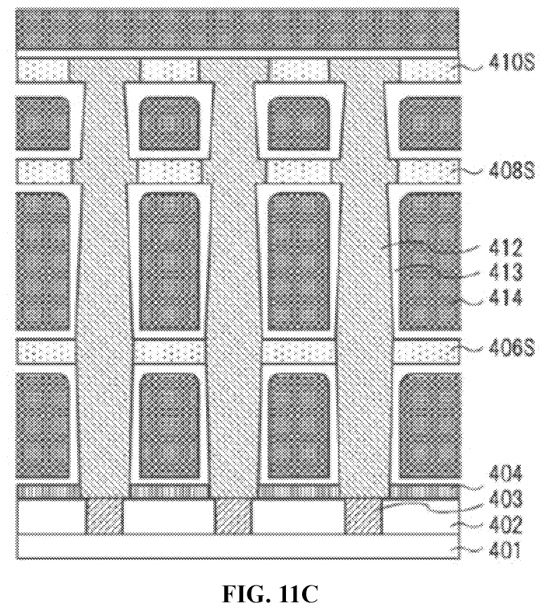

FIGS. 11A to 11C are views schematically showing a method of manufacturing a capacitor according to still another embodiment of the present invention. Hereinafter, only portions different from the previously described content will be described, and descriptions omitted hereinafter may be replaced with the previously described content.

As shown in FIG. 11A, as the mold layers are removed, the outer wall of the lower electrode 412 may be partially exposed, and the supporter layers 406S, 408S, 410S having etch selectivity with respect to the mold layers may remain without being removed, and the outer walls of the lower electrodes 412 may be supported by the supporter layers 406S, 408S, 410S.

Thereafter, the lower electrode 412 may be etched to improve the profile, and the etching of the lower electrode 412 may be performed by ALE (Atomic Layer Etching). At this time, the supporter layers 406S, 408S, 410S having etch selectivity with respect to the lower electrode 412 may not be damaged.

Meanwhile, as mentioned with reference to FIG. 3, the etching of the lower electrode 412 may be performed by sequentially supplying an etchant and a reactant. The etchant and the reactant are over-adsorbed at the upper portion and the diffusion and concentration thereof decrease toward the lower portion, similar to the behavior of a precursor. Therefore, the top critical dimension (TCD) of the lower electrode 412 can be expanded compared to the conventional process, and by repeating the process of sequentially supplying the etchant and the reactant for an appropriate number of cycles, a lower electrode 412 having a tapered shape in which the top critical dimension (TCD) is greater than the bottom critical dimension (BCD) can be formed.

Thereafter, as shown in FIG. 11B, a dielectric layer 413 may be formed. The dielectric layer 413 may be formed on the lower electrodes 412 and the supporter layers 406S, 408S, 410S, and a portion of the dielectric layer 413 may cover the lower structure. The dielectric layer 413 may include a high-k material having a higher dielectric constant than silicon oxide. The high-k material may include hafnium oxide (HfO2), zirconium oxide (ZrO2), aluminum oxide (Al2O3), titanium oxide (TiO2), tantalum oxide (Ta2O5), niobium oxide (Nb2O5), or strontium titanium oxide (SrTiO3). The dielectric layer 413 may also include a combination or a stacked structure thereof. In addition, the dielectric layer 413 may include a ZAZ (ZrO2/Al2O3/ZrO2) stack, a ZAZA (ZrO2/Al2O3/ZrO2/Al2O3) stack, a ZAZAT (ZrO2/Al2O3/ZrO2/Al2O3/TiO2) stack, a HAH (HfO2/Al2O3/HfO2) stack, a TZAZ (TiO2/ZrO2/Al2O3/ZrO2) stack, a TiO2/HfO2/Al2O3/HfO2 stack, a Ta2O5/ZrO2/Al2O3/ZrO2 stack, or a Ta2O5/HfO2/Al2O3/HfO2 stack.

Thereafter, as shown in FIG. 11C, an upper electrode 414 may be formed on the dielectric layer 413. The upper electrode 414 may fill a space between neighboring lower electrodes 412. The upper electrode 414 may extend to cover the upper portions of the lower electrodes 412. The upper electrode 414 may include polysilicon, silicon germanium, a metal, a metal nitride, a metal silicon nitride, a conductive metal oxide, a metal silicide, a noble metal, or a combination thereof. The upper electrode 414 may include at least one of titanium (Ti), titanium nitride (TiN), titanium silicon nitride (TiSiN), tantalum (Ta), tantalum nitride (TaN), titanium aluminum nitride (TiAlN), tungsten (W), tungsten nitride (WN), ruthenium (Ru), ruthenium oxide (RuO2), iridium (Ir), iridium oxide (IrO2), platinum (Pt), molybdenum (Mo), or a combination thereof.

According to the above description, a conformal dielectric layer can be formed, and the 5 effective area is increased, thereby increasing the dielectric constant. At this time, even if the dielectric layer 413 is over-adsorbed at the upper portion of the lower electrode 412 and the step coverage becomes 100% or less, in the final state in which the upper electrode 414 is formed, the upper/middle/lower cells can be formed relatively uniformly, thereby improving the reliability of the capacitor.

Although the present invention has been described in detail through the embodiments above, embodiments of other forms are also possible. Therefore, the technical spirit and scope of the claims described below are not limited to the embodiments.

What is claimed is:

1. A method of manufacturing a capacitor, comprising:
forming a plurality of lower electrodes and a supporter layer supporting the lower electrodes on a substrate;
etching the lower electrodes to expand a top critical dimension (TCD) of the lower electrodes;
forming a dielectric layer on the lower electrodes and the supporter layers; and
forming an upper electrode on the dielectric layer,
wherein, in the step of expanding the top critical dimension of the lower electrodes, an etching amount at an upper region of the lower electrode is greater than an etching amount at a lower region of the lower electrode.

2. The method of claim 1, wherein the step of etching the lower electrode is an ALE (Atomic Layer Etching) process, comprising:
supplying a reactant into a chamber in which the substrate is placed,
purging an interior of the chamber,
supplying an etchant into the interior of the chamber, and
purging the interior of the chamber.

3. The method of claim 2, wherein the reactant and the etchant are adsorbed relatively more at an upper region of the lower electrode and are adsorbed relatively less toward a lower region as a concentration thereof decreases.

4. The method of claim 2, wherein the reactant is provided as any one of O2, O3, H2O, and H2O2 alone, or in a mixture of at least two of O2, O3, H2O, and H2O2.

5. The method of claim 2, wherein the etchant is at least one of dimethylformamide-dimethylacetal and 1-chloromethyl ethyl ether.

6. The method of claim 1, wherein, in the step of etching the lower electrode, the supporter layer has an etch selectivity with respect to the lower electrode.

7. The method of claim 1, wherein the step of etching the lower electrode increases an aspect ratio of the lower electrode.

8. The method of claim 1, further comprising, between the step of expanding the top critical dimension of the lower electrodes and the step of forming the dielectric layer:
forming an insulating layer on the lower electrodes and the supporter layers; and
etching the insulating layer from a surface of the supporter layer.

9. The method of claim 8, wherein, in the step of etching the insulating layer, the insulating layer is selectively removed from the surface of the supporter layer.

10. The method of claim 1, wherein the lower electrode has a high aspect ratio of 1:10 or greater.

11. The method of claim 1, wherein the lower electrode comprises a metal, a metal nitride, a metal silicon nitride, a conductive metal oxide, a metal silicide, a noble metal, or a combination thereof.

12. The method of claim 1, wherein the supporter layer comprises silicon nitride (Si3N4), silicon carbon nitride (SiCN), silicon boron nitride, or a combination thereof.

13. The method of claim 1, wherein the dielectric layer comprises hafnium oxide (HfO2), zirconium oxide (ZrO2), aluminum oxide (Al2O3), titanium oxide (TiO2), tantalum oxide (Ta2O5), niobium oxide (Nb2O5), strontium titanium oxide (SrTiO3), or a combination or a stacked structure thereof.

14. The method of claim 8, wherein the insulating layer comprises niobium oxide, niobium nitride, niobium oxynitride, tantalum oxide, yttrium oxide, lanthanum oxide, or a combination thereof.

15. The method of claim 1, wherein, after the step of expanding the top critical dimension of the lower electrodes, the lower electrode has a tapered shape in which a top critical dimension (TCD) of the lower electrode is greater than a bottom critical dimension (BCD) of the lower electrode.

16. A method of manufacturing a memory device, comprising the method of manufacturing a capacitor according to claim 1.
